(19) United States
(12) Patent Application Publication
(10) Pub. No.: US 2010/0300670 A1
(43) Pub. Date: Dec. 2, 2010

(54) FIXING APPARATUS FOR HEAT SINK

(75) Inventor: ZHEN-XING YE, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (TW); HON HAI PRECISION INDUSTRY CO., LTD., Tu-Cheng (TW)

(21) Appl. No.: 12/565,769

(22) Filed: Sep. 24, 2009

(30) Foreign Application Priority Data
May 26, 2009 (CN) 200910302645.X

(51) Int. Cl. H01L 23/40; H01L 23/36

(52) U.S. Cl. 165/185

(57) ABSTRACT

A heat sink assembly includes a heat sink, and a fixing apparatus for fixing the heat sink. The fixing apparatus includes two fasteners to fix opposite ends of the heat sink, and a connecting piece connecting tops of the fasteners to abutting a top of the heat sink. A middle of the connecting piece is bent upwardly to depart from the top of the heat sink, to transfer pressing force to two portions of the connecting piece adjacent to the protruding portion, to allow the connecting piece to press a middle of the heat sink.

BACKGROUND

1. Technical Field

The present disclosure relates to a fixing apparatus for a heat sink.

2. Description of Related Art

Typically, a heat sink is mounted on a heat generating component in a computer chassis for dissipating heat. However, an elongated heat sink, such as a heat sink for a central processing unit voltage regulator, is fixed to a motherboard by two screws extending through two ends of the heat sink and engaging in the motherboard, which will lead to two ends of the heat sink bearing more force, and a center of the heat sink bearing comparatively small force. Because the heat sink bears force unevenly, heat conductive paste spread on a bottom of the heat sink cannot evenly contact the heat generating component, which will weaken the heat dissipating effect.

### BRIEF DESCRIPTION OF THE DRAWINGS

FIG. 1 is an assembled, isometric view of an embodiment of a fixing apparatus together with a heat sink.

FIG. 2 is an exploded, isometric view of the fixing apparatus and the heat sink of FIG. 1.

### DETAILED DESCRIPTION

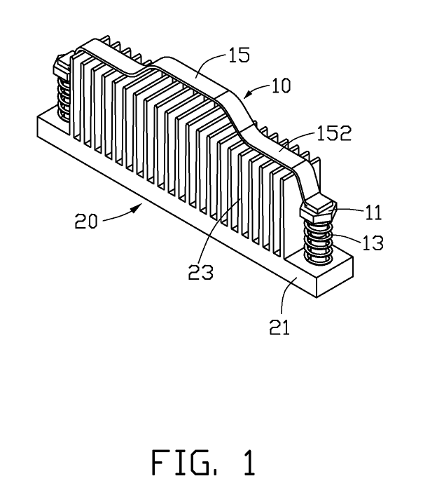

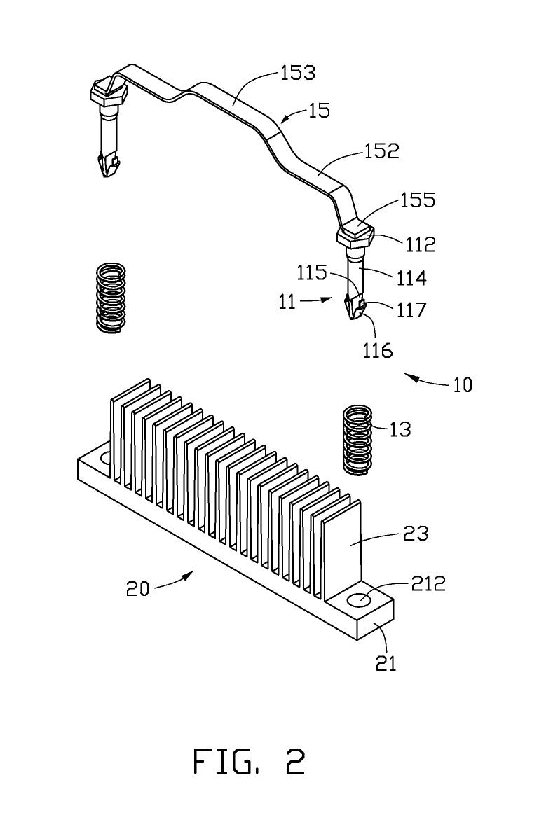

Referring to FIGS. 1 and 2, an embodiment of a fixing apparatus 10 is provided for attaching a heat sink 20 to an electronic component (not shown), and fixing the heat sink 20 to a motherboard (not shown) mounting the electronic component.

The heat sink 20 includes an elongated bottom plate 21. A bottom surface of the bottom plate 21 is coated with heat conductive paste. Two through holes 212 are defined in the bottom plate 21 adjacent to opposite ends of the bottom plate 21 respectively. A plurality of fins 23 are formed on the bottom plate 21 between the through holes 212.

The fixing apparatus 10 includes two fasteners 11, two elastic members 13, and a resilient connecting piece 15.

Each fastener 11 includes an end portion 112, and a post 114 extending down from a middle of the end portion 112. A plate 115 extends down from a distal end of the post 114. Two opposite hooks 116 extend upwardly and outwardly from a distal end of the plate 115, with a tab 117 extending upwardly from a top of each hook 116.

The connecting piece 15 includes an elongated main body 152. A middle of the main body 152 is bent upwardly to form a substantially arc-shaped protruding portion 153. Opposite ends of the main body 152 are bent downwardly and outwardly to respectively form an L-shaped connecting portion 155. The connecting portions 155 of the connecting piece 15 are connected to tops of the end portions 112 of the fasteners 11, respectively. In this embodiment, the fasteners 11 are integrally formed from the connecting portions 155 of the connecting piece 15.

In assembly, the hooks 116 of each fastener 11 are extended through a corresponding elastic member 13, to allow the elastic member 13 to fit about the corresponding post 114 of the fastener 11. The fixing apparatus 10 is pressed down from a top of the heat sink 20, to allow the hooks 116 of the fasteners 11 to correspondingly extend through the through holes 212 of the heat sink 20. The hooks 116 of each fastener 11 are engaged with the edge at one end of the corresponding through hole 212, and the tabs 117 of the hooks 116 are kept within the corresponding through hole 212. Thereby, the fixing apparatus 10 is fixed to the heat sink 20. Two ends of each elastic member 13 correspondingly abut against the bottom plate 21 of the heat sink 20 and the end portion 112 of a corresponding fastener 11. The heat sink 20 and the fixing apparatus 10 are placed on an electronic component of a motherboard (not shown). The fasteners 11 and the protruding portion 153 of the connecting piece 15 are pressed down, to allow the hooks 116 of the fasteners 11 to be deformed to extend through corresponding holes of the motherboard, and the main body 152 of the connecting piece 15 to abut tops of the plurality of fins 23 of the heat sink 20. The hooks 116 are restored to engage with the motherboard together with the tabs 117. Thereby, the heat sink 20 is fixed to the motherboard. The elastic members 13 are compressed between the bottom plate 21 and the end portions 112 of the corresponding fasteners 11, to provide pre-tightening force to the fasteners 11 and prevent the fasteners 11 from loosening. In this process, the protruding portion 153 transfers the pressing force to two portions of the main body 152 adjacent to the protruding portion 153, a middle section of the heat sink 20 is pressed by the portions of the main body 152 adjacent to the protruding portion 153, and two ends of the heat sink 20 are pressed by the fasteners 11. Therefore, the heat sink 20 bears force evenly across its body, and the heat conductive paste spread on the bottom surface of the heat sink 20 evenly contacts the electronic component, thus the heat sink 20 can efficiently dissipate heat for the electronic component.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A fixing apparatus for a heat sink, the fixing apparatus comprising:
two fasteners; and
a resilient connecting piece comprising an elongated main body, a middle of the main body bent upwardly to form a protruding portion, each of opposite ends of the main body bent downwardly to from a connecting portion, wherein the connecting portions are correspondingly connected to tops of the fasteners.

2. The fixing apparatus of claim 1, wherein the fasteners are integrally formed from the connecting portions of the connecting piece, respectively.

3. The fixing apparatus of claim 1, each of the fasteners comprises an end portion, and a post extending down from a middle of the end portion, a plate extends down from a distal end of the post, and two opposite hooks extend upwardly and outwardly from a distal end of the plate.

4. The fixing apparatus of claim 3, wherein a tab extends upwardly from a top of each of the hooks.

5. The fixing apparatus of claim 3, wherein two elastic members are correspondingly fitted about the posts of the fasteners.

6. The fixing apparatus of claim 1, wherein the connecting portions are L-shaped and bent downwardly and outwardly from the opposite ends of the main body.

7. The fixing apparatus of claim 1, wherein the protruding portion is substantially arc-shaped.

8. A heat sink assembly comprising:
a heat sink comprising an elongated bottom plate, and a plurality of fins formed on the bottom plate, two through holes defined in the bottom plate adjacent to opposite ends of the bottom plate, respectively;
a fixing apparatus comprising two fasteners to correspondingly extend through the through holes of the bottom plate, and a resilient connecting piece connecting tops of the fasteners, the resilient connecting piece comprising an elongated main body abutting tops of the plurality of fins, a middle of the main body bent upwardly to form a protruding portion depart from the plurality of fins, opposite ends of the main body bent downwardly to correspondingly connect the tops of the fasteners.

9. The heat sink assembly of claim 8, wherein the fasteners are integrally formed from the ends of the main body of the connecting piece, respectively.

10. The heat sink assembly of claim 8, each of the fasteners comprises an end portion, and a post extending down from a middle of the end portion, a plate extends down from a distal end of the post, and two opposite hooks extend upwardly and outwardly from a distal end of the plate and engaged with the edge at one end of the corresponding through hole.

11. The heat sink assembly of claim 10, wherein a tab extends upwardly from a top of each of the hooks, the tab is kept within the corresponding through hole.

12. The heat sink assembly of claim 10, wherein two elastic members are correspondingly fitted about the posts of the fasteners.

13. The heat sink assembly of claim 8, wherein the protruding portion is substantially arc-shaped.
